(19) United States
(12) Patent Application Publication
(10) Pub. No.: US 2014/0110469 A1
(43) Pub. Date: Apr. 24, 2014

(54) Glass Substrate Handling System, Cassette and Forklift Having the Same

(71) Applicants: Yongqiang Wang, Shenzhen (CN); Chunhao Wu, Shenzhen City (CN); Kunhsien Lin, Shenzhen City (CN); Minghu Qi, Shenzhen City (CN); Weibing Yang, Shenzhen City (CN); Zenghong Chen, Shenzhen City (CN); Zhenhua Guo, Shenzhen City (CN); Yunshao Jiang, Shenzhen City (CN); Zhiyou Shu, Shenzhen City (CN)

(72) Inventors: Yongqiang Wang, Shenzhen (CN); Chunhao Wu, Shenzhen City (CN); Kunhsien Lin, Shenzhen City (CN); Minghu Qi, Shenzhen City (CN); Weibing Yang, Shenzhen City (CN); Zenghong Chen, Shenzhen City (CN); Zhenhua Guo, Shenzhen City (CN); Yunshao Jiang, Shenzhen City (CN); Zhiyou Shu, Shenzhen City (CN)

(73) Assignee: Shenzhen China Star Optoelectronics Technology Co. Ltd., Shenzhen, Guangdong (CN)

(21) Appl. No.: 13/700,692

(22) PCT Filed: Oct. 30, 2012
(86) PCT No.: PCT/CN2012/083745

§ 371 Date: Nov. 28, 2012

(30) Foreign Application Priority Data
Oct. 24, 2012 (CN) 201210410023.0

(51) Int. Cl. H01L 21/677; G06K 19/06

(52) U.S. Cl. CPC H01L 21/677; G06K 19/06028
USPC 235/375; 235/494

(57) ABSTRACT

The present invention discloses a glass substrate handling system. The handling system includes a cassette and a forklift. The cassette for loading glass substrates includes a first marker and a second marker at two diagonal corners. The forklift includes a reader for reading information in the first marker or the second marker. The present invention further discloses a cassette for loading glass substrates and a forklift for handling glass substrates. The present invention deliveries the cassette between warehouses without turns.

### BACKGROUND OF THE INVENTION

1. Field of the Invention

The present invention relates to an automatic logistic warehouse technology, more particularly, to a glass substrate handling system, a cassette for loading glass substrates and a forklift for handling glass substrates.

2. Description of the Prior Art

In a LCD manufacturing process, a cassette loading glass substrates for producing liquid crystal panel is shipped to an autowarehouse by a loop wheel machine, and then a forklift in the autowarehouse handles the cassette to a storage location to store or to a process machine to further process. There is a strict limit of direction that glass substrates only move in and out the process machine from one side of the cassette, otherwise it scraps the LCD.

Conventionally, a marker is arranged at one side of the cassette and a reader is arranged on the forklift to judge the direction of the cassette by that the reader reading information in the marker. The cassette is carried if the direction of the cassette fits for the process demand, and on the contrary, it is necessary to turn the cassette around before the process if the direction of the cassette does not fit for the demand.

There is a limit of the direction for the glass substrates entering the process machine, but not for the delivery between warehouses. The conventional forklift, however, just reads the cassette in one direction and does not read the cassette in other direction until the cassette turns around In the meantime, it is necessary to turn the cassette around as transported from one side of the forklift to the other. The more turns of the glass substrates are, the more easily they break. And it increases transportation cost and decreases transportation efficiency if it uses a changeover device between warehouses to turn the cassette around.

### SUMMARY OF THE INVENTION

It is therefore a primary object of the present invention to provide a glass substrate handling system to pick and place a cassette between warehouses in a condition of maintenance of direction of the cassette.

According to the present invention, a glass substrate handling system comprises a cassette and a forklift. The cassette is used for loading the glass substrate. A first marker and a second marker are set up at two diagonal corners of the cassette. The forklift comprises a reader for reading information in the first marker or the second marker.

In one aspect of the present invention, the reader comprises a first reader and a second reader, and the first reader and the second reader are respectively set up at two diagonal corners of the forklift.

In another aspect of the present invention, the forklift further comprises a pick and place mechanism for picking and placing the cassette.

In another aspect of the present invention, the pick and place mechanism comprises a supporting mechanism and a slidable plate, the slidable plate slides along with the supporting mechanism, and the cassette is delivered from one side of the forklift to the opposite side of the forklift by the slidable plate.

In another aspect of the present invention, the pick and place mechanism further comprises a slide trail, and the slidable plate slides on the slide trail along with the supporting mechanism.

In another aspect of the present invention, the handling system further comprises a delivery device for delivering the cassette to the forklift by wheels.

In still another aspect of the present invention, a bar is arranged at the side of the cassette where the first marker is set up.

In yet another aspect of the present invention, the first marker and the second marker are bar code, and the reader is bar code reader.

According to the present invention, a cassette for loading glass substrates comprises a first marker and a second marker set up at two diagonal corners of the cassette.

In one aspect of the present invention, a bar is arranged at the side of the cassette where the first marker is set up.

In another aspect of the present invention, the first marker and the second marker are bar code.

According to the present invention, a forklift for handling glass substrates comprises a first reader and a second reader set up at two diagonal corners of the forklift. The first reader and the second reader are used for reading information in a marker on a cassette which loads the glass substrates.

In one aspect of the present invention, the forklift comprises a pick and place mechanism for picking and placing the cassette.

In another aspect of the present invention, the pick and place mechanism comprises a supporting mechanism and a slidable plate, the slidable plate slides along with the supporting mechanism, and the cassette is delivered from one side of the forklift to the opposite side of the forklift by the slidable plate.

In yet another aspect of the present invention, in the pick and place mechanism further comprises a slide trail, and the slidable plate slides on the slide trail along with the supporting mechanism.

In contrast to prior art, a first marker at one corner and a second marker at a diagonal corner of a cassette for loading glass substrates, and a reader on the forklift are proposed. The forklift handles the cassettees in any direction because the reader always reads information in the cassette. In hence, the forklift according to the embodiment in the present invention handles the cassette between warehouses without turns of the cassettes.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a system structure diagram of a glass substrate handling system according to an embodiment of the present invention.

FIG. 2 is a schematic diagram of a pick and place mechanism of a handling system in FIG. 1.

FIG. 3 is a diagram of a supporting mechanism and a slidable plate of the handling system in FIG. 1.

FIG. 4 shows a structure diagram of a delivery device of the handling system in FIG. 1.

### DETAILED DESCRIPTION OF THE PREFERRED EMBODIMENTS

The accompanying drawings and embodiments are included to provide a detailed description of the present invention.

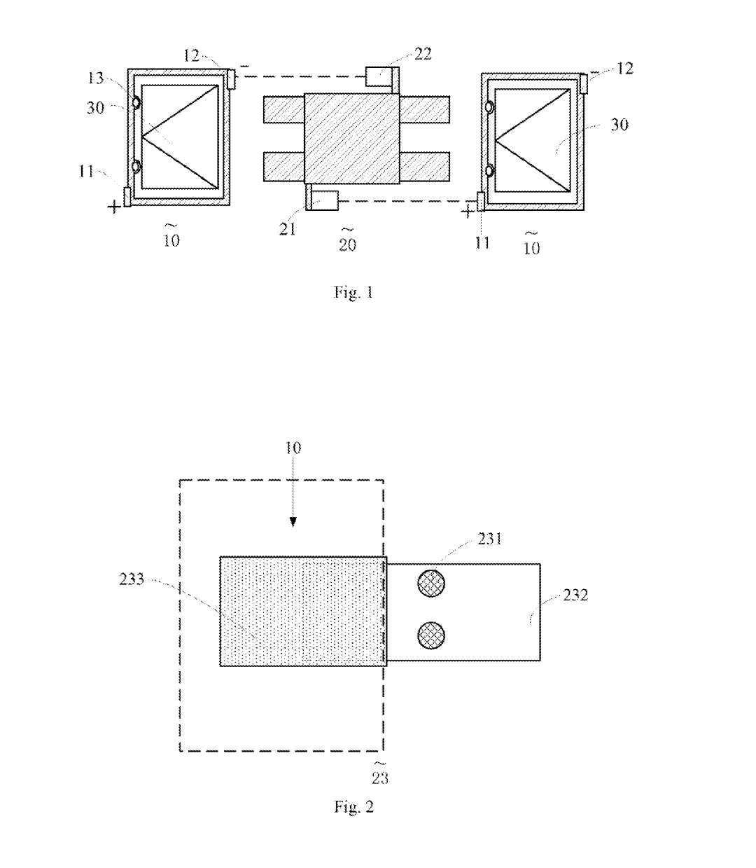

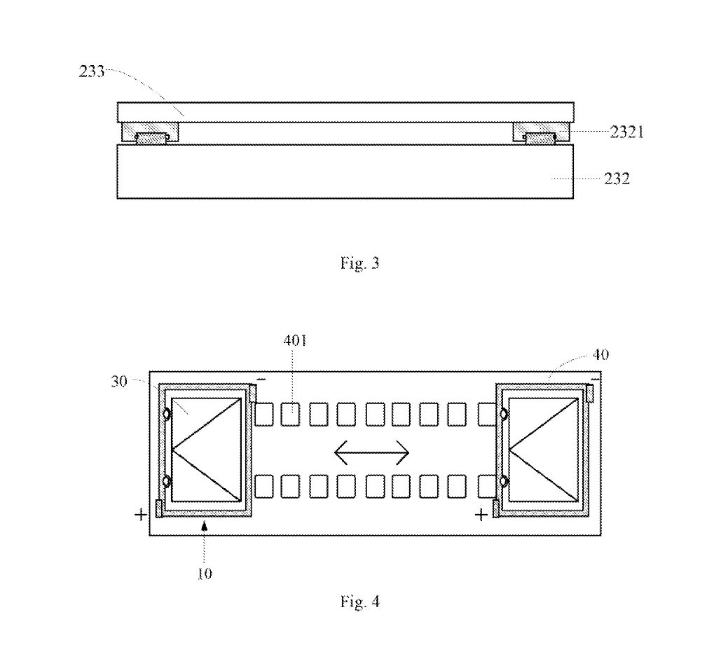

Please refer to FIG. 1 through FIG. 4. FIG. 1 is a system structure diagram of a glass substrate handling system according to an embodiment of the present invention FIG. 2 is a schematic diagram of a pick and place mechanism of a handling system in FIG. 1, FIG. 3 is a diagram of a supporting mechanism and a slidable plate of the handling system in FIG. 1, and FIG. 4 shows a structure diagram of a delivery device of the handling system in FIG. 1.

The glass substrate handling system according to the embodiment comprises a cassette 10, a forklift 20 and a delivery device 40.

A first marker 11 and a second marker 12 are arranged at two diagonal corners of the cassette 10 for loading a glass substrate 30. The present invention does not limit the specific positions of the first marker 11 and the second marker 12 on the cassette 10 because those depend on the specific position of a handling system, however, the first marker 11 and the second marker 12 preferably are set up symmetrically to the center of the cassette 10. It is noted that a bar 13 is arranged at the side of the cassette 10 where the first marker 11 is set up. The bar 13 for blocking the glass substrate 30 to move to the side of the first marker 11 keeps the glass substrate 30 at the side of the cassette 10 close to the second marker 12 when being moved in and out a process machine. The present invention does not limit which side of the cassette 10 the bar 13 is at, but the bar 13 of other embodiments is set up at the side of the cassette 10 where the second marker 12 is arranged.

A first reader 21 for reading information in the first marker 11 and a second reader 22 for reading information in the second marker 12 are respectively set up at two diagonal corners of the forklift 20. The present invention does not limit the specific positions of the first reader 21 and the second reader 22 on the forklift 20 as long as the first reader 21 and the second reader 22 are capable of reading the information in the first marker 11 or the second marker 12 because those positions depend on the specific position of a handling system, however, the first reader 21 and the second reader 22 preferably are set up symmetrically to the center of the forklift 20.

Preferably, the first marker 11 and the second marker 12 are bar code, and the first reader 21 and the second reader 22 are bar code readers. The present invention does not limit what marking elements the first marker 11 and the second marker 12 use as long as the first reader 21 and the second reader 22 use the corresponding reading elements. The first marker 11, the second marker 12, the first reader 21, and the second reader 22 are arranged in a manner as the one skilled in the art is aware, and further detailed description is omitted.

The forklift 20 further comprises a pick and place mechanism 23 for picking and placing the cassette 10. The pick and place mechanism 23 comprises a driving mechanism 231, a supporting mechanism 232 and a slidable plate 233. The slidable plate 233 slides along with the supporting mechanism 232 so that the cassette 10 is delivered from one side of the forklift 20 to the opposite side of the forklift 20 by the slidable plate 233. Specifically, the driving mechanism 231 is set up at the center of the supporting mechanism 232 which arranges a slide trail 2321. The driving mechanism 231 drives the slidable plate 233 to slide along with the slide trail 2321 to deliver the cassette 10 from one side of the forklift 20 to the opposite side of the forklift 20 when the cassette 10 is loaded on the slidable plate 233. It is noted that the slidable plate 233 is capable of sliding between two sides of the forklift 20 to pick and place at both sides of the forklift 20. The slidable plate 233 and the slide trail 2321 can be arranged in a manner as the one skilled in the art is aware, and further detailed description is omitted.

It does not need to turn the cassette 10 around when the cassette 10 is delivered from one side of the forklift 20 to the other side of the forklift 20 according to the embodiment in the present invention because it uses the slidable plate 233 to deliver the cassette 10. Therefore, it enhances efficiency of the forklift 20 due to decreased damage to glass substrates caused by rotating the cassette 10 in a warehouse. In addition, the use of the slidable plate 233 not only increases a distance of picking and placing the glass substrates but also avoid an interference between the pick and place mechanism 23 and warehouse frames.

The delivery device 40 comprises a wheel 401 The delivery device 40 deliveries a cassette to a forklift by the wheel 401.

The above-mentioned paragraphs introduce components and functions of the glass substrate handling system according to the embodiment. The following illustrates a delivery process of the cassette 10 according to the embodiment in the present invention in conjunction with Table 1. Table 1 is a comparison sheet of rotation of a forklift between the embodiment of the present invention and the prior art when the forklift deliveries the cassette 10 between different places.

TABLE 1

| | | Option | | | | | |
|---|---|---|---|---|---|---|---|
| Delivering | | | Direction of | Conventional way | | Present invention | |
| direction | | Status of cassette | cassette at end | Movement of | Status of cassette | Movement of | Status of cassette |
| Start | End | at start position | position | forklift | at end position | forklift | at end position |
| EQ | Non-EQ | Facing to | The same side of | Not turn around | Facing to forklift | Not turn around | Facing to forklift |
| Port | Port | forklift | forklift | | | | |
| | | | Opposite side of | Turn around | | Not turn around | Facing backward |
| | | | forklift | | | | forklift |
| | | Facing backward | The same side of | | | | |
| | | forklift | forklift | | | | |
| | | | Opposite side of | | | | |
| | | | forklift | | | | |
| | EQ | Facing to | The same side of | Not turn around | Facing to forklift | Not turn around | Facing to forklift |
| | Port | forklift | forklift | | | | |
| | | | Opposite side of | Turn around | | Turn around | |
| | | | forklift | | | | |
| | | Facing backward | The same side of | | | | |
| | | forklift | forklift | | | | |
| | | | Opposite side of | | | | |
| | | | forklift | | | | |
| Non- | Non-EQ | Facing to | The same side of | Not turn around | Facing to forklift | Not turn around | Facing to forklift |
| EQ | Port | forklift | forklift | | | | |
| Port | | | Opposite side of | Turn around | | Not turn around | Facing backward |
| | | | forklift | | | | forklift |
| | | Facing backward | The same side of | | | Not turn around | Facing backward |
| | | forklift | forklift | | | | forklift |
| | | | Opposite side of | | | Not turn around | Facing to forklift |
| | | | forklift | | | | |
| | EQ | Facing to | The same side of | Not turn around | Facing to forklift | Not turn around | Facing to forklift |
| | Port | forklift | forklift | | | | |
| | | | Opposite side of | Turn around | | Turn around | |
| | | | forklift | | | | |
| | | Facing backward | The same side of | | | Turn around | |
| | | forklift | forklift | | | | |
| | | | Opposite side of | | | Not turn around | |
| | | | forklift | | | | |

As Table 1 shows, a condition of the cassette 10 facing to the forklift 20 indicates the second marker 12 facing to the forklift 20. The cassette 10 faces the forklift 20 in the condition that the cassette 10 is delivered from EQ Port to non-EQ Port. And then the first reader 21 or the second reader 22 reads information in the first marker 11 or the second marker 12, and the cassette 10 is delivered to the end position through the move of the forklift 20 if the end position and the start position are at the same side of the forklift 20, but the cassette 10 is delivered to the end position through the slidable plate 233 of the forklift 20 if the end position and the start position are at the different sides of the forklift 20. Therefore, the forklift is capable of delivering the cassette 10 to the end position without turns.

If the cassette 10 is delivered from non-EQ Port or EQ Port to EQ port, the forklift 20 delivers the cassette 10 to the end position first and turns the cassette 10 around depending on whether the cassette 10 faces to the forklift 20. The forklift 20 does not turn the cassette 10 around if the cassette 10 faces the forklift 20 at the end position. On the contrary, the forklift 20 turns the cassette 10 around if the cassette 10 faces backwards the forklift 20 at the end position.

The first reader 21 or the second reader 22 is capable of reading information in the first marker 11 or the second marker 12 regardless of the direction of the cassette 10 facing the forklift 20 or the delivering direction of the forklift 20, when the cassette 10 is delivered from EQ Port to non-EQ Port. In hence, the forklift 20 is capable of delivering the cassette 10 without turns.

The delivery device 40 deliveries the cassette 10 by wheels to save delivery cost during, the delivery of the cassette 10 between warehouses. Besides that, it prevents glass substrates from damage in the turning process because it does not need to turn the cassette 10 during the delivery.

Noted that the glass substrate handling system of the embodiment in the present invention is used for handling not only liquid crystal glass substrates but also glass substrates with other uses. Another way for delivering other glass substrates which is realized by the one skilled in the art based on the embodiments of the present invention also belongs the scope of the present invention.

The cassette 10 comprises the first marker 11 and the second marker 12, and the forklift 20 comprises the first reader 21 and the second reader 22. The first reader 21 or the second reader 22 is capable of reading information in the cassette 10 no matter of the direction of the cassette 10 facing the forklift 20. In hence, the forklift 20 is capable of delivering, the cassette 10 between warehouses without turns. Furthermore, the arrangement of the slidable plate 233 on the forklift 20 makes the forklift 20 pick and place the cassette 10 at two sides of the forklift 20 without turning the cassette 10 to decrease turns of the cassette 10 in warehouses. The delivery device 40 deliveries the cassette 10 by wheels to save delivering cost. The decreased turns of the cassette 10 during the delivery avoids damage to glass substrates in the turning process so that it enhances delivering efficiency and lessens cost.

The embodiment in the present invention also provides a cassette for loading a glass substrate. A first marker and a second marker are respectively set up at the across corners of the cassette, and a reader on the forklift of the handling system is capable of reading information in the first marker and the second marker. In hence, the forklift handles the cassette. There is no further description for the specific structure of the cassette because it has been made above.

A first marker and a second marker are respectively set up at the across corners of the cassette, The reader on the forklift is capable of reading information in the cassette no matter of the direction of the cassette facing the forklift. In hence, the forklift is capable of picking and placing the cassette between warehouses without turns.

The embodiment in the present invention further provides a forklift for handling glass substrates. A first reader and a second reader for reading information in the markers on the cassette carrying glass substrates are respectively set up at the across corners of the forklift. There is no further description for the specific structure of the forklift because it has been made above.

The first reader and the second reader of the embodiment in the present invention are respectively set up at the across corners of the forklift so that the forklift is capable of picking and placing the cassette in dual directions to enhance the efficiency.

While the present invention has been described in connection with what is considered the most practical and preferred embodiments, it is understood that this invention is not limited to the disclosed embodiments but is intended to cover various arrangements made without departing from the scope of the broadest interpretation of the appended claims.

What is claimed is:

1. A glass substrate handling, system comprising:
a cassette, for loading the glass substrate, a first marker and a second marker respectively set up at two diagonal corners of the cassette;
a forklift, comprising a reader for reading information in the first marker or the second marker.

2. The handling system of claim 1, wherein the reader comprises a first reader and a second reader, and the first reader and the second reader are respectively set up at two diagonal corners of the forklift.

3. The handling system of claim 2, wherein the forklift further comprises a pick and place mechanism for picking and placing the cassette.

4. The handling system of claim 3, wherein the pick and place mechanism comprises a supporting mechanism and a slidable plate, the slidable plate slides along with the supporting mechanism, and the cassette is delivered from one side of the forklift to the opposite side of the forklift by the slidable plate.

5. The handling system of claim 4, wherein the pick and place mechanism further comprises a slide trail, and the slidable plate slides on the slide trail along with the supporting mechanism.

6. The handling system of claim 1 further comprising a delivery device for delivering the cassette to the forklift by wheels.

7. The handling, system of claim 1, wherein a bar is arranged at the side of the cassette where the first marker is set up.

8. The handling system of claim 1, wherein the first marker and the second marker are bar code, and the reader is bar code reader.

9. A cassette for loading glass substrates, comprising a first marker and a second marker set up at two diagonal corners of the cassette.

10. The cassette of claim 9, wherein a bar is arranged at the side of the cassette where the first marker is set up.

11. The cassette of claim 9, wherein the first marker and the second marker are bar code.

12. A forklift for handling glass substrates, comprising a first reader and a second reader set up at two diagonal corners of the forklift, the first reader and the second reader for reading information in a marker on a cassette which loads the glass substrates.

13. The forklift of claim 12 further comprising a pick and place mechanism for picking and placing the cassette.

14. The forklift of claim 13, wherein the pick and place mechanism comprises a supporting mechanism and a slidable plate, the slidable plate slides along with the supporting mechanism, and the cassette is delivered from one side of the forklift to the opposite side of the forklift by the slidable plate.

15. The forklift of claim 14, wherein the pick and place mechanism further comprises a slide trail, and the slidable plate slides on the slide trail along with the supporting mechanism.
